(19) United States
(12) Patent Application Publication
(10) Pub. No.: US 2023/0140254 A1
(43) Pub. Date: May 4, 2023

(54) ENERGY HARVESTING SYSTEM USING SOLAR CELL AND THERMOELECTRIC DEVICE

(71) Applicant: Korea University Research and Business Foundation, Seoul (KR)

(72) Inventors: Sang Sig KIM, Seoul (KR); Kyoung Ah CHO, Seoul (KR); Yoon Beom PARK, Seoul (KR); Seung Gen YANG, Seoul (KR); Tae Ho PARK, Seoul (KR); Jae Hwan LEE, Seoul (KR)

(21) Appl. No.: 17/574,441

(22) Filed: Jan. 12, 2022

(30) Foreign Application Priority Data
Oct. 29, 2021 (KR) 10-2021-0146995

(51) Int. Cl. H02S 40/44; H01L 35/28; H01L 35/16; H01L 35/22

(52) U.S. Cl. CPC H02S 40/44; H01L 35/28; H01L 35/16; H01L 35/22

(57) ABSTRACT

The present disclosure relates to an energy harvesting system for generating electrical energy by using a solar cell and a thermoelectric device. The energy harvesting system according to one embodiment of the present disclosure may include a solar cell for generating electrical energy based on sunlight; an interface layer located under the solar cell and including a heat transfer layer for transferring heat generated by the solar cell; a thermoelectric device located under the interface layer, including a first electrode, a second electrode, and a thermoelectric channel located between the first and second electrodes, and configured to generate electrical energy based on a temperature difference between the first and second electrodes that occurs when heat generated by the solar cell is transferred to the first electrode through the heat transfer layer; and a cooling layer located under the thermoelectric device and cooling the second electrode to increase the temperature difference.

### CROSS-REFERENCE TO RELATED APPLICATION

This application claims priority to Korean Patent Application No. 10-2021-0146995, filed on Oct. 29, 2021 in the Korean Intellectual Property Office, the disclosure of which is incorporated herein by reference.

### BACKGROUND OF THE DISCLOSURE

### Field of the Disclosure

The present disclosure relates to an energy harvesting system for generating electrical energy by using a solar cell and a thermoelectric device, and more particularly, to technology for improving the energy generation efficiency of an energy harvesting system by effectively transferring heat generated in a solar cell and heat induced by light passing through the solar cell to the upper portion of a thermoelectric device by including an interface layer between the solar cell and the thermoelectric device and by cooling the lower portion of the thermoelectric device without additional power consumption by including a cooling layer under the thermoelectric device.

### Description of the Related Art

Recently, as depletion of existing energy resources such as oil and coal is predicted, interest in alternative energy sources capable of replacing the existing energy resources is increasing.

Thereamong, solar cells are particularly attracting attention because solar energy resources are abundant and do not cause environmental pollution.

The solar cell includes a solar cell using solar heat that generates electricity required to rotate a turbine using solar heat and a solar cell using sunlight that converts sunlight into electrical energy by using the properties of a semiconductor.

A solar cell has a junction structure of a p-type semiconductor and an n-type semiconductor like a diode. When light is incident on a solar cell, due to interaction between light and a material constituting the semiconductor of the solar cell, negatively (−) charged electrons and positively (+) charged holes created as a result of loss of electrons are generated. At this time, current flows by movement of the electrons and the holes.

Meanwhile, as an energy harvesting device, a solar cell may immediately convert an energy source such as heat or sunlight existing in the vicinity into electrical energy. However, since the intensity of the energy source changes depending on surrounding environments, the amount of generated electrical energy is limited.

The energy harvesting device is a device that generates electrical energy using sunlight, heat, friction, pressure, or the like, and may include a solar cell, a thermoelectric device, a triboelectric device, and a piezoelectric device.

To increase the amount of electrical energy generated using ambient temperature, energy systems using energy harvesting devices are being developed.

However, in energy harvesting technology according to the prior art, the amount of electrical energy generated by an energy harvesting device is limited, and improvement is required in terms of electrical energy production.

In addition, research on energy harvesting technology for generating electrical energy using sunlight, heat, friction, pressure, or the like is being actively conducted.

As the amount of energy used in daily life increases, research related to energy generation using sunlight or micro thermal energy and development of a useful power source are required.

In addition, for practical use of an energy harvesting device, it is essential to develop a system having a high degree of integration and to increase the amount of power produced per area.

To improve power generation efficiency and storage efficiency per area, an energy generation device and an energy storage device are fabricated using lithography, which is a semiconductor process technology.

A capacitor stores a voltage through a thermoelectric device. When a heat source is removed and the thermoelectric device stops generating power, the voltage stored in the direction of the thermoelectric device is discharged, and current is generated. In this case, the generated current is referred to as reverse current.

To prevent and block reverse current, various methods using circuits may be implemented. The most common method is to block reverse current through a diode.

However, in order for a diode to operate, a minimum voltage called a turn-on voltage is required, which may consume the generated voltage of a thermoelectric device, which is a disadvantage of the diode.

When a thermoelectric device generates a high voltage, the turn-on voltage of a diode does not cause a serious problem. However, when a thermoelectric device generates power using micro energy, a voltage generated by the thermoelectric device may be considerably consumed by the turn-on voltage of a diode.

Conventionally, a heat sink used as a cooling system must have a surface area of a certain size or more for effective heat exchange, which may cause problems related to size and structure in an energy harvesting system that is a fusion device of a solar cell and a thermoelectric device.

In addition, although an air cooling system and a water cooling system have excellent cooling efficiency, these systems have a disadvantage in that an additional power source is required.

### RELATED ART DOCUMENTS

### Patent Documents

Korean Patent No. 10-1771148, “SOLAR HEAT COLLECTOR TYPE THERMOELECTRIC GENERATOR MODULE AND SYSTEM INCLUDING THE SAME”
Korean Patent Application Publication No. 10-2019-0073895, “SOLAR CELL THERMOELECTRIC FUSION DEVICE”
Korean Patent No. 10-2280224, “THERMOELECTRIC GATE SOLAR CELL” Korean Patent No. 10-1956682, “SOLAR CELL THERMOELECTRIC FUSION DEVICE”

### SUMMARY OF THE DISCLOSURE

Therefore, the present disclosure has been made in view of the above problems, and it is an object of the present disclosure to improve the energy generation efficiency of an energy harvesting system by effectively transferring heat generated in a solar cell and heat induced by light passing through the solar cell to the upper portion of a thermoelectric device by including an interface layer between the solar cell and the thermoelectric device and by cooling the lower portion of the thermoelectric device without additional power consumption by including a cooling layer under the thermoelectric device.

It is another object of the present disclosure to improve the performance of an energy harvesting system by improving the performance of a solar cell and the power generation performance of a thermoelectric device by dissipating heat of the solar cell without an additional power source by using a cooling patch layer made of a hygroscopic polymer or a radiative cooling layer that minimizes absorption of light of a sunlight spectrum and radiates heat under the radiative cooling layer to the outside to cool the surface temperature of a material or the temperature under the material.

It is still another object of the present disclosure to provide an energy harvesting system capable of maximizing space utilization by including an interface layer between a solar cell and a thermoelectric device, generating electrical energy through the solar cell, and generating electrical energy using heat of the solar cell through the thermoelectric device.

It is still another object of the present disclosure to provide an energy harvesting system capable of solving problems caused by heat generation of a solar cell by transferring heat generated by the solar cell and heat caused by absorption of infrared rays passing through the solar cell to a thermoelectric device and improving the power generation performance of the thermoelectric device.

It is still another object of the present disclosure to provide an energy harvesting system with increased space utilization between a solar cell and a thermoelectric device by selectively including an interface layer having either a double structure or an island arrangement structure between the solar cell and the thermoelectric device.

It is still another object of the present disclosure to provide an energy harvesting system, characterized in that, when heat is transferred to a thermoelectric device, a phase change material forming the thermoelectric channel of the thermoelectric device acts as the thermoelectric channel to generate electricity, and when heat is not transferred to the thermoelectric device, the phase change material acts as a resistance channel and acts as a thermal switch to block reverse current caused by discharging of voltage stored in a charging device such as a capacitor without using an additional component such as a diode.

It is still another object of the present disclosure to provide an energy harvesting system capable of increasing the lifespan and operating time of products when applied to wearable devices, non-powered sensors, household devices, industrial devices, and the like and serving as a core power supply source in various devices including household devices and industrial devices by using natural energy.

It is yet another object of the present disclosure to provide an energy harvesting system that creates social and cultural innovation when applied to the 4th industry and wearable devices and helps overcome the energy crisis.

In accordance with one aspect of the present disclosure, provided is an energy harvesting system including a solar cell for generating electrical energy based on sunlight; an interface layer located under the solar cell and including a heat transfer layer for transferring heat generated by the solar cell; a thermoelectric device located under the interface layer, including a first electrode, a second electrode, and a thermoelectric channel located between the first and second electrodes, and configured to generate electrical energy based on a temperature difference between the first and second electrodes that occurs when heat generated by the solar cell is transferred to the first electrode through the heat transfer layer; and a cooling layer located under the thermoelectric device and cooling the second electrode to increase the temperature difference.

The cooling layer may be formed of any one of a cooling patch layer formed of a hygroscopic polymer and a radiative cooling layer formed by coating or dyeing the second electrode with a paint solution prepared by mixing a solvent and a binder for mechanically connecting nanoparticles or microparticles, a particle size and composition of which are determined by considering infrared emissivity and reflectance to incident sunlight in a wavelength range corresponding to a sky window and surfaces of the nanoparticles or microparticles.

The cooling patch layer may have a three-dimensional network structure and a porous structure to store moisture, wherein, during daytime, the stored moisture evaporates and cools the second electrode, and during night time, supercooled vapor in an air liquefies on a surface that has a higher humidity than surroundings, allowing the cooling patch layer to store additional moisture.

The cooling patch layer may be formed of any one polymer of a polyacrylic acid-based polymer, a polyvinyl alcohol-based polymer, a polyvinylpyrrolidone-based polymer, and a natural polymer, wherein the natural polymer includes at least one of carrageenan, agar, glucomannan, sodium alginate, gum arabic, and cellulose derivatives.

The nanoparticles or microparticles may include a mixture of at least one nanoparticle or microparticle material of SiO₂, Al₂O₃, CaCO₃, CaSO₄, c-BN, ZrO₂, MgHPO₄, Ta₂O₅, AlN, LiF, MgF₂, HfO₂, and BaSO₄ and the at least one nanoparticle or microparticle material, and the binder may include at least one binder material of dipentaerythritol hexaacrylate (DPHA), polytetrafluoroethylene (PTFE), polyurethane acrylate (PUA), ethylene tetra fluoro ethylene (ETFE), polyvinylidene fluoride (PVDF), an acrylic polymer, a polyester-based polymer, and a polyurethance-based polymer.

The radiative cooling layer may cool the second electrode by absorbing and emitting long wavelength infrared rays of 8 μm to 13 μm corresponding to the wavelength range corresponding to a sky window based on the infrared emissivity and reflecting ultraviolet rays and near infrared rays of 0.3 μm to 2.5 μm corresponding to the incident sunlight based on the reflectance.

The interface layer may include an infrared absorption layer for absorbing infrared rays passing through the solar cell, the heat transfer layer may transfer heat based on the infrared absorption layer to the first electrode, and the thermoelectric device may generate electrical energy by using both heat generated by the solar cell and heat based on the infrared absorption layer.

The interface layer may be formed in any one of a dual structure and an island arrangement structure, wherein, in the dual structure, the infrared absorption layer is disposed on the heat transfer layer, and the dual structure is configured to absorb infrared rays passing through the solar cell and transfer, to the thermoelectric device, heat based on the absorbed infrared rays and heat generated by the solar cell when the solar cell is exposed to sunlight, and, in the island structure, the heat transfer layer is locally disposed on the infrared absorption layer, and the island structure is configured to absorb infrared rays passing through the solar cell and transmit, to the thermoelectric device, heat based on the absorbed infrared rays and heat generated by the solar cell when the solar cell is exposed to sunlight.

The infrared absorption layer may be formed of a carbon-based material, and the heat transfer layer may be formed of at least one heat conductive material of boron nitride (BN), reduced graphene oxide (rGO), aluminum nitride (AlN), silicon carbide (SiC), and beryllium oxide (BeO).

The first and second electrodes may be formed of any one metal material of Au, Al, Pt, Ag, Ti, and W, and the thermoelectric channel may be formed of any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂.

The solar cell may include at least one of a silicon (Si) solar cell, a dye-responsive solar cell, a monocrystalline solar cell, a polycrystalline solar cell, and a thin-film solar cell.

The thermoelectric device may include the thermoelectric channel consisting of a first thermoelectric channel and a second thermoelectric channel, any one of the first and second thermoelectric channels may be formed of a phase change material, and the other may be formed of a thermoelectric material, wherein, when heat is transferred from the heat transfer layer, the phase change material operates as a thermoelectric channel, and when heat is not transferred, the phase change material operates as a resistance channel to block reverse current caused by discharging of voltage in a capacitor charged with the generated electrical energy.

The first thermoelectric channel may be formed of any one of VO₂, Cd₂Os₂O₇, NdNiO₃, SmNiO₃, and GdNiO₃ as the phase change material, may operate as a p-type thermoelectric channel when a heat source based on the transferred heat is located, and may operate as a resistance channel when the heat source is not located, and the second thermoelectric channel may be formed of any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂ as the thermoelectric material and may operate as an n-type thermoelectric channel regardless of the heat source.

In the any one thermoelectric channel, when temperature exceeds a phase transition temperature band, the phase change material may be in a first state in which the phase change material operates as the thermoelectric channel; when the temperature is below the phase transition temperature band, the phase change material may be in a second state in which the phase change material operates as the resistance channel; and when the temperature is within the phase transition temperature band, the phase change material may be in a transition state between the thermoelectric channel and the resistance channel.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 illustrates an energy harvesting system using a solar cell and a thermoelectric device according to one embodiment of the present disclosure;

FIG. 2 shows a cross-sectional view of an energy harvesting system using a solar cell and a thermoelectric device according to one embodiment of the present disclosure;

FIGS. 3A and 3B are drawings for explaining a cooling layer in the form of a cooling patch applied to an energy harvesting system using a solar cell and a thermoelectric device according to one embodiment of the present disclosure;

FIGS. 4A to 4C are drawings for explaining a cooling layer conforming to a radiative cooling method applied to an energy harvesting system using a solar cell and a thermoelectric device according to one embodiment of the present disclosure;

FIGS. 5A and 5B are graphs for explaining temperature change based on a cooling layer in the form of a cooling patch applied to an energy harvesting system using a solar cell and a thermoelectric device according to one embodiment of the present disclosure;

FIG. 6 illustrates an energy harvesting system using a solar cell and a thermoelectric device according to one embodiment of the present disclosure;

FIG. 7 shows a cross-sectional view of an energy harvesting system using a solar cell and a thermoelectric device according to one embodiment of the present disclosure;

FIGS. 8A and 8B are drawings for explaining various structures of an interface layer applied to a space between a solar cell and a thermoelectric device in an energy harvesting system according to one embodiment of the present disclosure;

FIG. 9 is a graph for explaining the absorption characteristics of an infrared absorption layer constituting an interface layer according to one embodiment of the present disclosure;

FIGS. 10A and 10B include a graph and an image for explaining the exothermic characteristics of an infrared absorption layer constituting an interface layer according to one embodiment of the present disclosure;

FIG. 11 illustrates an energy harvesting system using a thermoelectric device including a phase change material according to one embodiment of the present disclosure;

FIG. 12 illustrates an energy harvesting system when a heat source is present in the vicinity of a thermoelectric device including a phase change material according to one embodiment of the present disclosure;

FIG. 13 illustrates an energy harvesting system when a heat source is not located in the vicinity of a thermoelectric device including a phase change material according to one embodiment of the present disclosure; and

FIG. 14 is a graph for explaining the operating state of a thermoelectric device including a phase change material according to one embodiment of the present disclosure.

### DETAILED DESCRIPTION OF THE DISCLOSURE

Hereinafter, the embodiments of the present disclosure will be described in detail with reference to the drawings.

However, it should be understood that the present disclosure is not limited to the embodiments according to the concept of the present disclosure, but includes changes, equivalents, or alternatives falling within the spirit and scope of the present disclosure.

In the following description of the present disclosure, detailed description of known functions and configurations incorporated herein will be omitted when it may make the subject matter of the present disclosure unclear.

In addition, the terms used in the specification are defined in consideration of functions used in the present disclosure, and can be changed according to the intent or conventionally used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), it may be directly connected or coupled to the other element or an intervening element (e.g., third) may be present.

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do ˜” with other devices or components.

For example, in the sentence “processor configured to perform A, B, and C”, the processor may refer to a general purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless mentioned otherwise or clearly inferred from context, the expression “x uses a or b” means any one of natural inclusive permutations.

Terms, such as “unit” or “module”, etc., should be understood as a unit that processes at least one function or operation and that may be embodied in a hardware manner, a software manner, or a combination of the hardware manner and the software manner.

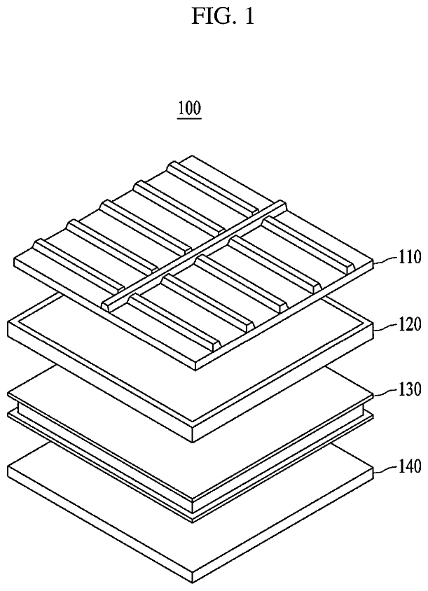

FIG. 1 illustrates an energy harvesting system using a solar cell and a thermoelectric device according to one embodiment of the present disclosure.

FIG. 1 illustrates an energy harvesting system for generating electrical energy including an interface layer between a solar cell and a thermoelectric device according to one embodiment of the present disclosure, wherein the heat of the solar cell is effectively transferred to the thermoelectric device through the interface layer, and the lower portion of the thermoelectric device is cooled to increase the temperature difference between both surfaces of the thermoelectric device.

Referring to FIG. 1, an energy harvesting system 100 according to one embodiment of the present disclosure includes a solar cell 110, an interface layer 120, a thermoelectric device 130, and a cooling layer 140.

For example, the energy harvesting system 100 may be a fusion device in which the solar cell 110 and the thermoelectric device 130 are fused.

According to one embodiment of the present disclosure, the energy harvesting system 100 is a system in which the solar cell 110 for converting sunlight energy into electrical energy and the thermoelectric device 130 for converting thermal energy into electrical energy are integrated. The energy harvesting system 100 may be an energy harvesting system that generates power from sunlight or irregular energy generated in a surrounding environment and supports the use of the generated power.

For example, the energy harvesting system 100 may include the interface layer 120 to maximize space utilization and thermal conductivity between the solar cell 110 and the thermoelectric device 130, and may include the cooling layer 140 to increase a temperature difference between the first and second electrodes of the thermoelectric device 130 and dissipate heat from the solar cell 110.

According to one embodiment of the present disclosure, the interface layer 120 transfers heat generated when the solar cell 110 is exposed to sunlight and heat generated by absorption of infrared rays (IR) passing through the solar cell 110 to the thermoelectric device 130, so that a temperature difference between both electrodes of the thermoelectric device 130 increases, thereby improving the power generation performance of the thermoelectric device 130.

For example, the interface layer 120 may include an infrared absorption layer for absorbing infrared rays and a heat transfer layer for transferring the heat of a solar cell and heat caused by absorption of infrared rays. In this case, the infrared absorption layer may be selectively excluded.

For example, heat generated in the solar cell 110 may include heat that increases the temperature of the solar cell 110, such as heat generated by exposure to sunlight and heat generated when the solar cell 110 converts sunlight energy into electrical energy.

In the thermoelectric device 130, thermoelectric channels formed of a p-type thermoelectric material and an n-type thermoelectric material are formed vertically, and electrodes are disposed at the top and bottom of the thermoelectric channel. In this case, the electrodes include a first electrode receiving heat from the solar cell and a second electrode positioned opposite the first electrode.

Here, the first electrode may correspond to a hot side, the second electrode may correspond to a cold side, the first electrode may be referred to as a hot electrode, and the second electrode may be referred to as a cold electrode.

For example, the solar cell 110 may include at least one of a silicon (Si) solar cell, a dye-responsive solar cell, a monocrystalline solar cell, a polycrystalline solar cell, and a thin-film solar cell.

That is, as the solar cell 110, various types of solar cells such as a silicon (Si) solar cell, a dye-responsive solar cell, a monocrystalline solar cell, a polycrystalline solar cell, and a thin-film solar cell may be used.

According to one embodiment of the present disclosure, the cooling layer 140 may be located under the thermoelectric device 130, and may cool the lower portion of the thermoelectric device 130 to increase a temperature difference between both electrodes of the thermoelectric device 130, thereby solving a problem of heat generation of the solar cell 110.

Accordingly, the present disclosure may improve the energy generation efficiency of an energy harvesting system by effectively transferring heat generated in a solar cell and heat induced by light passing through the solar cell to the upper portion of a thermoelectric device by including an interface layer between the solar cell and the thermoelectric device and by cooling the lower portion of the thermoelectric device without additional power consumption by including a cooling layer under the thermoelectric device.

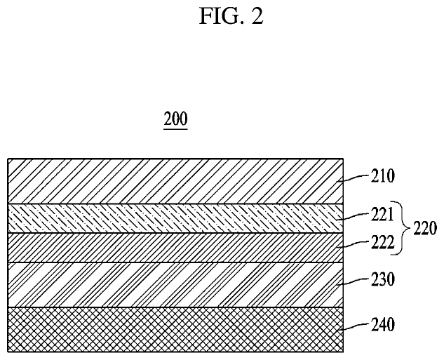

FIG. 2 shows a cross-sectional view of an energy harvesting system using a solar cell and a thermoelectric device according to one embodiment of the present disclosure.

Referring to FIG. 2, an energy harvesting system 200 according to one embodiment of the present disclosure includes a solar cell 210, an interface layer 220, a thermoelectric device 230, and a cooling layer 240.

Since the energy harvesting system 200 according to one embodiment of the present disclosure includes the interface layer 220, utilization of the space between the solar cell 210 and the thermoelectric device 230 may be improved, thermal conductivity between the solar cell 210 and the thermoelectric device 230 may be increased, and heat based on infrared rays passing through the solar cell 210 may also be used for power generation of the thermoelectric device 230.

In addition, since the energy harvesting system 200 includes the cooling layer 240 under the thermoelectric device 230, heat of the solar cell 210 may be efficiently dissipated, and a temperature difference between the first and second electrodes of the thermoelectric device 230 may be increased, thereby improving the power generation performance of the thermoelectric device 230.

According to one embodiment of the present disclosure, the solar cell 210 may generate electrical energy based on sunlight.

For example, the interface layer 220 is located under the solar cell 210, and includes an infrared absorption layer 221 for absorbing infrared rays passing through the solar cell 210 and a heat transfer layer 222 for transferring heat generated by the solar cell 210 and heat based on the infrared absorption layer 221.

For example, the infrared absorption layer 221 may be formed of a carbon-based material, and the heat transfer layer 222 may be formed of at least one heat conductive material of boron nitride (BN), reduced graphene oxide (rGO), aluminum nitride (AlN), silicon carbide (SiC), and beryllium oxide (BeO).

According to one embodiment of the present disclosure, the thermoelectric device 230 may be located under the interface layer 220, and may include a first electrode, a second electrode, and a thermoelectric channel located between the first and second electrodes.

In the thermoelectric device 230, heat generated by the solar cell 210 and heat based on the infrared absorption layer 221 are transferred to the first electrode through the heat transfer layer 222, and electrical energy is generated based on a temperature difference between the first and second electrodes.

The cooling layer 240 according to one embodiment of the present disclosure is located under the thermoelectric device 230, and is placed in contact with the second electrode of the thermoelectric device 230 to cool the second electrode, thereby increasing a temperature difference between the first and second electrodes of the thermoelectric device 230.

For example, the thermoelectric device 230 may include the first electrode corresponding to a hot electrode and the second electrode corresponding to a cold electrode, and may generate electrical energy based on a temperature difference between the first and second electrodes. In this case, as a temperature difference between the first and second electrodes increases, the amount of generated electrical energy may increase.

Accordingly, in the thermoelectric device 230, the temperature of the first electrode may be increases by heat transferred through the heat transfer layer 222, and the temperature of the second electrode may be decreased due to cooling by the cooling layer 240. As a result, a temperature difference between both electrodes may be increased based on increase in the first electrode and decrease in the second electrode, and the amount of generated electrical energy may be increased based on the increased temperature difference.

According to one embodiment of the present disclosure, the cooling layer 240 may be formed of any one of a cooling patch layer formed of a hygroscopic polymer and a radiative cooling layer formed by coating or dyeing the second electrode with a paint solution prepared by mixing a solvent and a binder for mechanically connecting nanoparticles or microparticles, the particle size and composition of which are determined by considering infrared emissivity and reflectance to incident sunlight in a wavelength range corresponding to the sky window and the surfaces of the nanoparticles or microparticles.

Here, the radiative cooling layer may cool the second electrode corresponding to the lower portion of the radiative cooling layer through radiative cooling based on a direction in which sunlight is incident.

Accordingly, the present disclosure may improve the performance of an energy harvesting system by improving the performance of a solar cell and the power generation performance of a thermoelectric device by dissipating heat of the solar cell without an additional power source by using a cooling patch layer made of a hygroscopic polymer or a radiative cooling layer that minimizes absorption of light of a sunlight spectrum and radiates heat under the radiative cooling layer to the outside to cool the surface temperature of a material or the temperature under the material.

In addition, the present disclosure may provide an energy harvesting system capable of maximizing space utilization by including an interface layer between a solar cell and a thermoelectric device, generating electrical energy through the solar cell, and generating electrical energy using heat of the solar cell through the thermoelectric device.

According to one embodiment of the present disclosure, the thermoelectric device 230 may include the thermoelectric channel consisting of a first thermoelectric channel and a second thermoelectric channel, any one of the first and second thermoelectric channels may be formed of a phase change material, and the other may be formed of a thermoelectric material.

In the thermoelectric device 230, when heat is transferred from the heat transfer layer 222, the phase change material may operate as a thermoelectric channel. When heat is not transferred, the phase change material may operate as a resistance channel to block reverse current caused by discharging of voltage in a capacitor charged with generated electrical energy.

For example, a case in which heat is not transferred may correspond to a nigh time when the energy harvesting system 200 is not exposed to sunlight.

For example, the first thermoelectric channel may be formed of VO₂, which is a phase change material. When a heat source based on heat transferred through the heat transfer layer 222 is located, the first thermoelectric channel may operate as a p-type thermoelectric channel. When the heat source is not located, the first thermoelectric channel may operate as a resistance channel.

The second thermoelectric channel may be formed of any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂, which are thermoelectric materials, and may be operate as an n-type thermoelectric channel regardless of a heat source.

Accordingly, the present disclosure may provide an energy harvesting system, characterized in that, when heat is transferred to a thermoelectric device, a phase change material forming the thermoelectric channel of the thermoelectric device acts as the thermoelectric channel to generate electricity, and when heat is not transferred to the thermoelectric device, the phase change material acts as a resistance channel and acts as a thermal switch to block reverse current caused by discharging of voltage stored in a charging device such as a capacitor without using an additional component such as a diode.

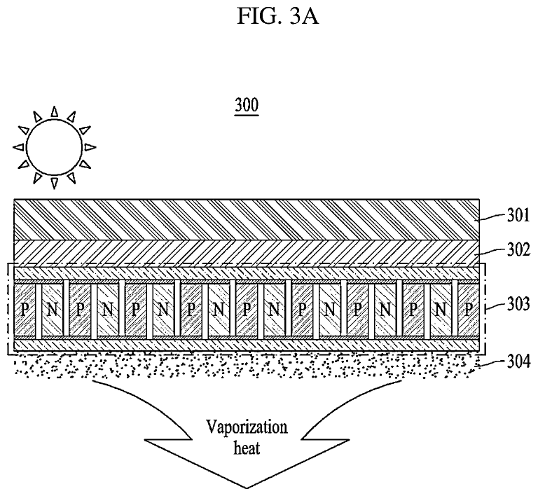

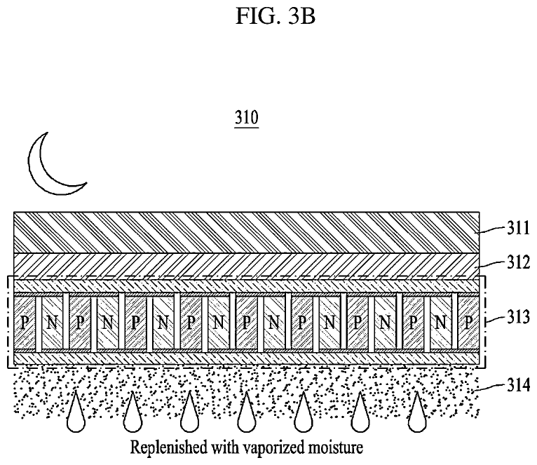

FIGS. 3A and 3B are drawings for explaining a cooling layer in the form of a cooling patch applied to an energy harvesting system using a solar cell and a thermoelectric device according to one embodiment of the present disclosure.

FIG. 3A illustrates an operation of a cooling patch layer during the day in an energy harvesting system according to one embodiment of the present disclosure.

Referring to FIG. 3A, an energy harvesting system 300 according to one embodiment of the present disclosure includes a solar cell 301, an interface layer 302, a thermoelectric device 303, and a cooling patch layer 304.

For example, the cooling patch layer 304 may have a three-dimensional network structure and a porous structure to store moisture. During the daytime, moisture previously stored in the cooling patch layer 304 may evaporate, so that the second electrode located on the lower side of the thermoelectric device 303 may be cooled.

According to one embodiment of the present disclosure, the cooling patch layer 304 may cool the second electrode through vaporization heat accompanying evaporation of stored moisture.

For example, the cooling patch layer 304 is formed of a polymer having a large amount of hydrophilic groups, and the cooling patch layer 304 does not dissolve in a solution and may absorb and store a solution weighing tens to hundreds of times the weight thereof. Heat of the solar cell 301 may be dissipated by a phenomenon in which stored moisture is vaporized while absorbing the surrounding heat.

FIG. 3B illustrates an operation of a cooling patch layer during the night time in an energy harvesting system according to one embodiment of the present disclosure.

Referring to FIG. 3B, an energy harvesting system 310 according to one embodiment of the present disclosure includes a solar cell 311, an interface layer 312, a thermoelectric device 313, and a cooling patch layer 314.

For example, the cooling patch layer 314 may have a three-dimensional network structure and a porous structure to store moisture. During the night time, supercooled airborne vapor liquefies on a surface that has a higher humidity than surroundings, allowing the cooling patch layer 314 to store additional moisture.

That is, during the night time, as supercooled vapor liquefies on a surface that has a higher humidity than surroundings, the cooling patch layer 313 is replenished with vaporized moisture, allowing the cooling patch layer 313 to store additional moisture.

According to one embodiment of the present disclosure, the cooling patch layer stores moisture during the night time and evaporates the stored moisture during the day time to dissipate heat, so that the lower portion of the thermoelectric device may be cooled without power.

The cooling patch layer may be formed of any one of a polyacrylic acid-based polymer, a polyvinyl alcohol-based polymer, a polyvinylpyrrolidone-based polymer, and a natural polymer.

For example, the natural polymer may include at least one of carrageenan, agar, glucomannan, sodium alginate, gum arabic, and cellulose derivatives.

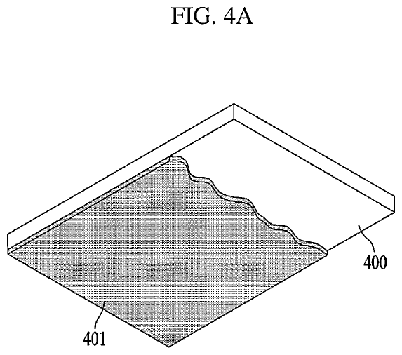

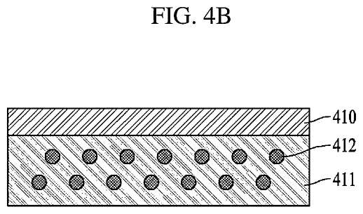

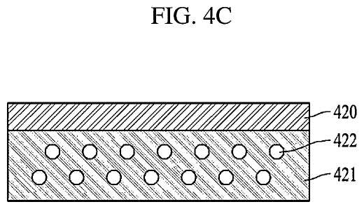

FIGS. 4A to 4C are drawings for explaining a cooling layer conforming to a radiative cooling method applied to an energy harvesting system using a solar cell and a thermoelectric device according to one embodiment of the present disclosure.

FIG. 4A illustrates a radiative cooling layer of a paint coating film implemented with nanoparticles or microparticles in the energy harvesting system using a solar cell and a thermoelectric device according to one embodiment of the present disclosure, and illustrates a structure for cooling the second electrode of a thermoelectric device.

Referring to FIG. 4A, according to one embodiment of the present disclosure, a radiative cooling layer 401 is formed on a second electrode 400 of the thermoelectric device.

According to one embodiment of the present disclosure, when the radiative cooling layer 401 that reduces temperature below the ambient temperature without consuming energy both during the day when sunlight is present and at night when there is no sunlight is implemented, the radiative cooling layer 401 may be applied to the surface of a material requiring cooling, such as an electrode, a building, and a vehicle, to perform a cooling function without consuming energy.

Since the radiative cooling layer 401 has sections each having a partially high emissivity within the sky window, emissivity within the sky window may also be higher.

In addition, the radiative cooling layer 401 is a paint coating film. Since materials forming the radiative cooling layer 401 are inexpensive, abundant, and applicable to solution processing, a polymer-based radiative cooling layer may be manufactured at low cost through a large-area process.

According to one embodiment of the present disclosure, the radiative cooling layer 401 may be formed by coating or dyeing various surfaces with a paint solution prepared by mixing a solvent and a binder for mechanically connecting nanoparticles or microparticles, the particle size and composition of which are determined by considering infrared emissivity and reflectance to incident sunlight in a wavelength range corresponding to the sky window and the surfaces of the nanoparticles or microparticles.

For example, the nanoparticles or microparticles may include a mixture of at least one nanoparticle or microparticle material of SiO₂, Al₂O₃, CaCO₃, CaSO₄, c-BN, ZrO₂, MgHPO₄, Ta₂O₅, AlN, LiF, MgF₂, HfO₂, and BaSO₄ and at least one nanoparticle or microparticle material of SiO₂, Al₂O₃, CaCO₃, CaSO₄, c-BN, ZrO₂, MgHPO₄, Ta₂O₅, AlN, LiF, MgF₂, HfO₂, and BaSO₄.

According to one embodiment of the present disclosure, the radiative cooling layer 401 may be formed so that the infrared emissivity and reflectance of each of nanoparticles or microparticles overlap to improve infrared emissivity and reflectance.

According to one embodiment of the present disclosure, the binder forming the radiative cooling layer 401 may include at least one binder material of dipentaerythritol hexaacrylate (DPHA), polytetrafluoroethylene (PTFE), polyurethane acrylate (PUA), ethylene tetra fluoro ethylene (ETFE), polyvinylidene fluoride (PVDF), an acrylic polymer, a polyester-based polymer, and a polyurethance-based polymer.

For example, the radiative cooling layer 401 may have an increased infrared emissivity based on infrared emissivity in a wavelength range corresponding to the sky window of the at least one binder material.

According to one embodiment of the present disclosure, the radiative cooling layer 401 may be formed by coating or dyeing various surfaces with a paint solution prepared by mixing nanoparticles or microparticles and a binder in a volume ratio of x:1. Here, x may range from 0.2 to 2.5.

For example, the radiative cooling layer 401 may cool the second electrode by absorbing and emitting long wavelength infrared rays of 8 μm to 13 μm corresponding to a wavelength range corresponding to the sky window based on infrared emissivity and reflecting ultraviolet rays and near infrared rays of 0.3 μm to 2.5 μm corresponding to incident sunlight based on reflectance.

For example, the various surfaces may include at least one of a wooden surface, a glass surface, the surface of a metal substrate, the surface of an umbrella, the surface of a house model, and a cloth surface.

According to one embodiment of the present disclosure, the radiative cooling layer 401 may be formed by coating or dyeing various surfaces with a paint solution through at least one solution process of spin coating, bar coating, spray coating, doctor blading, and blade coating.

For example, the paint solution according to one embodiment of the present disclosure arbitrarily controls the size or composition of various types of nanoparticles or microparticles having high bandgap energy and partially high emissivity for long wavelength infrared rays of 8 to 13 μm corresponding to a wavelength range of the sky window, thereby ensuring high absorption (emissivity) over the entire region of the wavelength range of the sky window. The paint solution may be prepared by dispersing a binder material for mechanically connecting the surfaces of various types of nanoparticles or microparticles in a solvent.

When a binder material is added to mixed nanoparticles or microparticles, the nanoparticles or microparticles may be connected to each other to increase adhesion, thereby increasing durability.

From the viewpoint of optical properties, reflection of sunlight may be enhanced due to scattering at the interface between nanoparticles or microparticles having a high refractive index and a polymer binder material having a low refractive index.

In addition, a polymeric binder material also has an extinction coefficient in the sky window, which may contribute to the high emissivity of a paint layer.

According to one embodiment of the present disclosure, the radiative cooling layer 401 absorbs less sunlight than conventional paint, and has a relatively high emissivity within the wavelength range of the sky window. Thus, the radiative cooling layer 401 has excellent radiative cooling performance.

In addition, when additional additives are included in the radiative cooling layer 401, the adhesive strength, surface properties, and external resistance thereof may be changed.

The present disclosure may provide a radiative cooling layer prepared by forming a paint coating film having excellent radiative cooling performance on various surfaces. The radiative cooling layer may minimize absorption of light in the sunlight spectrum and emit heat under the radiative cooling layer to the outside to decrease the surface temperature of a material or the temperature under the material.

For example, based on the incident angle of sunlight, the lower portion of the radiative cooling layer may correspond to a second electrode, which is a lower portion of the thermoelectric device.

In addition, the present disclosure may provide a radiative cooling layer on which a paint coating film that absorbs less sunlight than conventional paint, has a high emissivity in the sky window, and thus has excellent radiative cooling performance is formed.

In addition, the present disclosure may provide a rigid or flexible radiative cooling layer by forming a paint coating film on a rigid or flexible substrate.

FIG. 4B illustrates a case in which a radiative cooling layer according to one embodiment of the present disclosure is formed in a structure in which particles are dispersed in a polymer matrix.

Referring to FIG. 4B, the radiative cooling layer according to one embodiment of the present disclosure may consist of a polymer matrix 411 and nanoparticles or microparticles 412, and may be formed in at least one layer that is formed on a second electrode 410 of the thermoelectric device and is formed by dispersing the nanoparticles or microparticles 412 of an inorganic material in the polymer matrix 411 based on a polymer material.

Specifically, the radiative cooling layer may be disposed under the second electrode formed of a metal material. The nanoparticles or microparticles 412 of an inorganic material may be mixed and dispersed in the polymer matrix 411 having a high emissivity in the sky window to form a selective emissive layer under the second electrode 410.

In addition, the polymer matrix 411 and the nanoparticles or microparticles 412 of an inorganic material may reflect near infrared rays and ultraviolet rays of sunlight based on a difference in refractive indexes between the polymer matrix 411 and the nanoparticles or microparticles 412.

FIG. 4C illustrates a case in which the radiative cooling layer according to one embodiment of the present disclosure is formed in a polymer pore structure.

Referring to FIG. 4C, in the radiative cooling layer according to one embodiment of the present disclosure, a selective emissive layer may be formed so that a polymer material 421 and pores 422 for absorbing and emitting long wavelength infrared rays are formed under a second electrode 420 formed of a metal material of the thermoelectric device.

That is, in the radiative cooling layer, the selective emissive layer may serve to reflect near infrared rays.

The selective emissive layer according to one embodiment of the present disclosure may be formed in at least one layer that reflects near infrared rays by scattering and reflecting incident sunlight based on a difference in refractive indexes between the polymer material 421 and the pores 422.

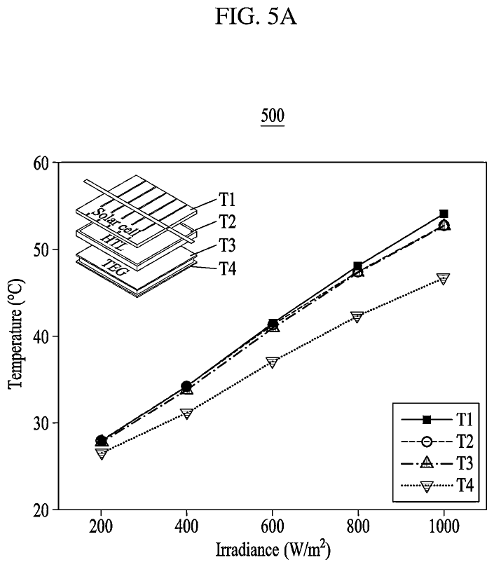

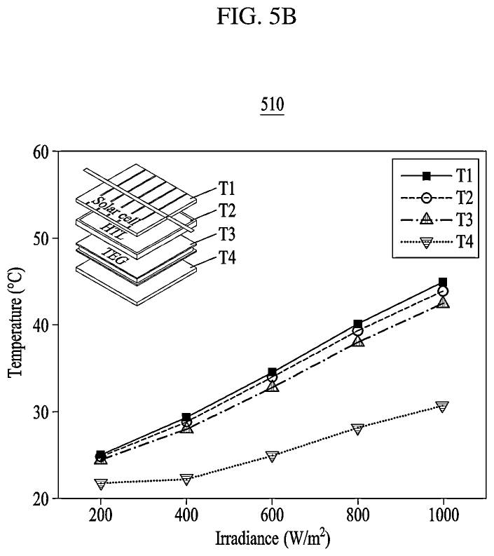

FIGS. 5A and 5B are graphs for explaining temperature change based on a cooling layer in the form of a cooling patch applied to an energy harvesting system using a solar cell and a thermoelectric device according to one embodiment of the present disclosure.

FIG. 5A is a graph showing a temperature distribution in an energy harvesting system using a solar cell and a thermoelectric device according to the prior having a structure in which a cooling layer is not formed under the thermoelectric device.

FIG. 5B is a graph showing a temperature distribution in an energy harvesting system using a solar cell and a thermoelectric device according to one embodiment of the present disclosure having a structure in which a cooling layer is formed under the thermoelectric device.

A graph 500 of FIG. 5A shows changes in the first temperature (T1), the second temperature (T2), the third temperature (T3), and the fourth temperature (T4) according to irradiance of sunlight.

The first temperature (T1) represents the temperature of a solar cell, the second temperature (T2) represents the temperature of a heat transfer layer, the third temperature (T3) represents the temperature of the upper portion of a thermoelectric device, and the fourth temperature (T4) represents the temperature of the lower portion of the thermoelectric device.

A graph 510 of FIG. 5B shows changes in the first temperature (T1), the second temperature (T2), the third temperature (T3), and the fourth temperature (T4) according to irradiance of sunlight.

The first temperature (T1) represents the temperature of a solar cell, the second temperature (T2) represents the temperature of a heat transfer layer, the third temperature (T3) represents the temperature of the upper portion of a thermoelectric device, and the fourth temperature (T4) represents the temperature of the lower portion of the thermoelectric device cooled based on a cooling layer.

The temperature changes shown in the graph 500 and the graph 510 are summarized in Table 1. The graph 500 is referred to as a first example, and the graph 510 is referred to as a second example.

TABLE 1

| | First example ( °C.) | | | | | Second example (° C.) | | | | |
|---|---|---|---|---|---|---|---|---|---|---|
| Irradiance (W/m²) | T1 | T2 | T3 | T4 | ΔT | T1 | T2 | T3 | T4 | ΔT |
| 200 | 27.8 | 27.9 | 27.8 | 26.5 | 1.3 | 24.9 | 24.8 | 24.5 | 21.7 | 2.8 |
| 400 | 34.2 | 33.9 | 33.8 | 31.1 | 2.7 | 29.3 | 28.8 | 28.0 | 22.3 | 5.7 |
| 600 | 41.5 | 41.0 | 41.0 | 37.1 | 3.9 | 34.6 | 34.0 | 32.9 | 25.0 | 7.9 |
| 800 | 48.2 | 47.5 | 47.4 | 42.3 | 5.1 | 40.2 | 39.3 | 38.0 | 28.2 | 9.8 |
| 1000 | 54.1 | 52.8 | 52.8 | 46.7 | 6.1 | 45.0 | 43.9 | 42.5 | 30.7 | 11.8 |

Referring to Table 1, when irradiance is 200 W/m² to 1,000 W/m², a difference (ΔT) between the first temperature (T1) and the fourth temperature (T4) is 1.3° C. to 6.1° C. in the first example and 2.8° C. to 11.8° C. in the second example.

That is, it can be confirmed that, in the energy harvesting system using a solar cell and a thermoelectric device according to one embodiment of the present disclosure, the temperature difference between both sides of the thermoelectric device is further increased based on the cooling layer.

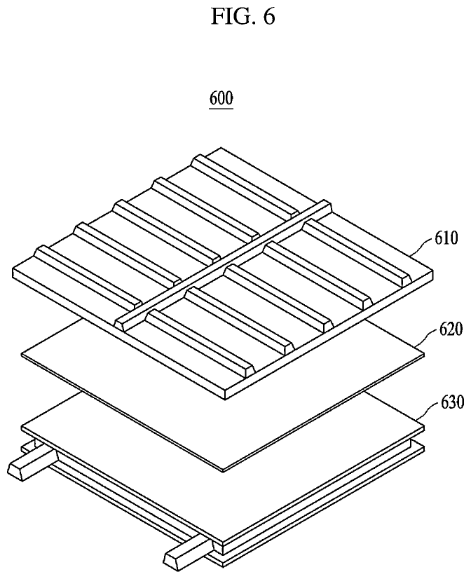

FIG. 6 illustrates an energy harvesting system using a solar cell and a thermoelectric device according to one embodiment of the present disclosure.

FIG. 6 illustrates an energy harvesting system including an interface layer between a solar cell and a thermoelectric device according to one embodiment of the present disclosure and configured to effectively transfer heat of the solar cell to the thermoelectric device through the interface layer to generate electrical energy.

Referring to FIG. 6, an energy harvesting system 600 according to one embodiment of the present disclosure includes a solar cell 610, an interface layer 620, and a thermoelectric device 630.

According to one embodiment of the present disclosure, the energy harvesting system 600 may be a system in which the solar cell 610 for converting sunlight energy into electrical energy and the thermoelectric device 630 for converting thermal energy into electrical energy are integrated. The energy harvesting system 600 may be an energy harvesting system that generates power from sunlight or irregular energy generated in a surrounding environment and supports the use of the generated power.

For example, the energy harvesting system 600 includes the interface layer 620 to maximize space utilization and thermal conductivity between the solar cell 610 and the thermoelectric device 630.

According to one embodiment of the present disclosure, the interface layer 620 transfers heat generated when the solar cell 610 is exposed to sunlight and heat generated by absorption of infrared rays (IR) passing through the solar cell 610 to the thermoelectric device 630, so that a temperature difference between both electrodes of the thermoelectric device 630 increases, thereby improving the power generation performance of the thermoelectric device 630.

Accordingly, the present disclosure may improve the energy generation efficiency of the energy harvesting system by efficiently transferring heat of the solar cell to the upper portion of the thermoelectric device through the interface layer disposed between the solar cell and the thermoelectric device.

For example, heat generated by the solar cell 610 may include heat that increases the temperature of the solar cell 610, such as heat generated by exposure to sunlight and heat generated when the solar cell 610 converts sunlight energy into electrical energy.

In the thermoelectric device 630, thermoelectric channels formed of a p-type thermoelectric material and an n-type thermoelectric material are formed vertically, and electrodes are disposed at the top and bottom of the thermoelectric channel. In this case, the electrodes include a first electrode receiving heat from the solar cell and a second electrode positioned opposite the first electrode.

Here, the first electrode may correspond to a hot side, the second electrode may correspond to a cold side, the first electrode may be referred to as a hot electrode, and the second electrode may be referred to as a cold electrode.

For example, the thermoelectric channels may include a first thermoelectric channel and a second thermoelectric channel. The first thermoelectric channel may be referred to as a p-type thermoelectric channel, and the second thermoelectric channel may be referred to as an n-type thermoelectric channel.

According to one embodiment of the present disclosure, the energy harvesting system 600 may be formed by coating the upper portion of the thermoelectric device 630 with the interface layer 620 and then bonding the thermoelectric device 630 and the solar cell 610.

For example, the solar cell 610 may include at least one of a silicon (Si) solar cell, a dye-responsive solar cell, a monocrystalline solar cell, a polycrystalline solar cell, and a thin-film solar cell.

That is, as the solar cell 610, various types of solar cells including a silicon (Si) solar cell, a dye-responsive solar cell, a monocrystalline solar cell, a polycrystalline solar cell, and a thin-film solar cell may be used.

Accordingly, the present disclosure may provide an energy harvesting system capable of increasing the lifespan and operating time of products when applied to wearable devices, non-powered sensors, household devices, industrial devices, and the like and serving as a core power supply source in various devices including household devices and industrial devices by using natural energy.

In addition, the present disclosure may provide an energy harvesting system that creates social and cultural innovation when applied to the 4th industry and wearable devices and helps overcome the energy crisis.

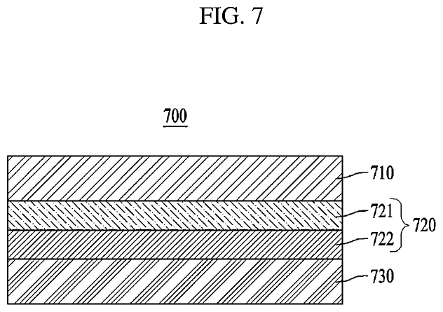

FIG. 7 shows a cross-sectional view of an energy harvesting system using a solar cell and a thermoelectric device according to one embodiment of the present disclosure.

FIG. 7 illustrates a structure of an energy harvesting system including an interface layer in addition to a solar cell and a thermoelectric device according to one embodiment of the present disclosure.

Referring to FIG. 7, an energy harvesting system 700 according to one embodiment of the present disclosure includes a solar cell 710, an interface layer 720, and a thermoelectric device 730.

For example, the interface layer 720 includes an infrared absorption layer 721 and a heat transfer layer 722.

Since the energy harvesting system 700 according to one embodiment of the present disclosure includes the interface layer 720, space utilization between the solar cell 710 and the thermoelectric device 730 may be improved, thermal conductivity between the solar cell 710 and the thermoelectric device 730 may be increased, and heat based on infrared rays passing through the solar cell 710 may also be used for power generation by the thermoelectric device 730.

For example, in the energy harvesting system 700, the interface layer 720 is located under the solar cell 710, and the thermoelectric device 730 is located under the interface layer 720.

According to one embodiment of the present disclosure, the solar cell 710 may generate electrical energy based on sunlight.

For example, the solar cell 710 may include at least one of a silicon (Si) solar cell, a dye-responsive solar cell, a monocrystalline solar cell, a polycrystalline solar cell, and a thin-film solar cell.

For example, the interface layer 720 includes the infrared absorption layer 721 for absorbing infrared rays passing through the solar cell 710 and the heat transfer layer 722 for transferring heat generated by the solar cell and heat based on the infrared absorption layer 721.

For example, the infrared absorption layer 721 may be formed of a carbon-based material, and the heat transfer layer 222 may be formed of at least one heat conductive material of boron nitride (BN), reduced graphene oxide (rGO), aluminum nitride (AlN), silicon carbide (SiC), and beryllium oxide (BeO).

According to one embodiment of the present disclosure, the interface layer 720 may be formed in any one of a dual structure and an island arrangement structure.

Here, the dual structure may refer to a dual structure of the infrared absorption layer 721 and the heat transfer layer 722, and the island arrangement structure may refer to a structure in which the heat transfer layer 722 is arranged at intervals like islands on the infrared absorption layer 721.

According to one embodiment of the present disclosure, the thermoelectric device 730 includes a first electrode, a second electrode, and a thermoelectric channel positioned between the first and second electrodes.

The first electrode is located on the solar cell 710 side, and the second electrode is located on the opposite side. Thus, the first electrode may be a hot electrode, and the second electrode may be a cold electrode.

For example, in the thermoelectric device 730, heat generated by the solar cell and heat based on the infrared absorption layer may be transferred to the first electrode through the heat transfer layer, which causes a temperature difference between the first and second electrodes. Based on the temperature difference, electrical energy may be generated.

For example, the thermoelectric device 730 may be a thermoelectric device that generates electricity using the Seebeck effect that generates an electromotive force when a temperature difference between the first and the second electrodes occurs.

According to one embodiment of the present disclosure, the first and second electrodes may be formed of any one metal material of Au, Al, Pt, Ag, Ti, and W.

For example, the thermoelectric channel may be formed of any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂.

According to one embodiment of the present disclosure, in the energy harvesting system 700, since the interface layer 720 is disposed between the solar cell 710 and the thermoelectric device 730, space utilization may be maximized, electrical energy may be generated by the solar cell 710, and the thermoelectric device 730 may generate electrical energy using heat generated by the solar cell.

In addition, in the energy harvesting system 700, by including the thin interface layer 720, a fusion device with improved space utilization and capable of maintaining the performance of the solar cell 710 may be implemented.

Accordingly, the present disclosure may provide an energy harvesting system capable of maximizing space utilization by including an interface layer between a solar cell and a thermoelectric device, generating electrical energy through the solar cell, and generating electrical energy using heat of the solar cell through the thermoelectric device.

In addition, the present disclosure may provide an energy harvesting system capable of solving problems caused by heat generation of a solar cell by transferring heat generated by the solar cell and heat caused by absorption of infrared rays passing through the solar cell to a thermoelectric device and improving the power generation performance of the thermoelectric device.

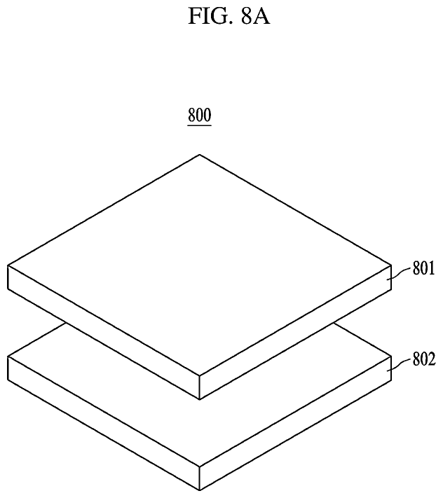

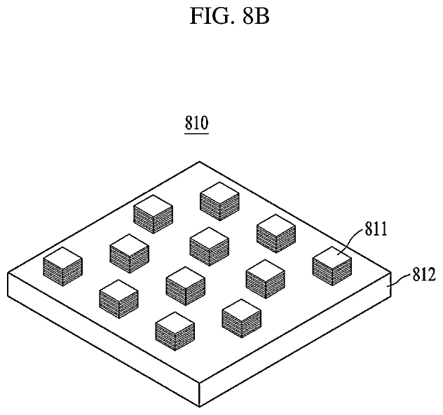

FIGS. 8A and 8B are drawings for explaining various structures of an interface layer applied to a space between a solar cell and a thermoelectric device in an energy harvesting system according to one embodiment of the present disclosure.

FIG. 8A illustrates a dual structure related to an interface layer applied to an energy harvesting system according to one embodiment of the present disclosure.

Referring to FIG. 8A, an interface layer 800 according to one embodiment of the present disclosure includes an infrared absorption layer 801 and a heat transfer layer 802.

For example, the interface layer 800 is formed in a dual structure of the infrared absorption layer 801 and the heat transfer layer 802.

According to one embodiment of the present disclosure, in the interface layer 800 of the dual structure, the infrared absorption layer 801 may be located on the heat transfer layer 802, and heat caused by absorption of infrared rays passing through the solar cell and heat generated by the solar cells when the solar cell is exposed to sunlight may be transferred to the thermoelectric device.

That is, the interface layer 800 may improve the power generation performance of the thermoelectric device based on the infrared absorption layer 801 and the heat transfer layer 802 covering all contactable areas of the solar cell and the thermoelectric device.

In addition, to efficiently use heat generated by the solar cell and generate additional energy from the thermoelectric device, the interface layer 800 may be included in the energy harvesting system.

FIG. 8B illustrates an island arrangement structure related to an interface layer applied to an energy harvesting system according to one embodiment of the present disclosure.

Referring to FIG. 8B, an interface layer 810 according to one embodiment of the present disclosure includes a heat transfer layer 811 and an infrared absorption layer 812.

For example, the interface layer 810 is formed in an island arrangement structure in which heat transfer materials constituting the heat transfer layer 811 are formed on the infrared absorption layer 812.

That is, the interface layer 810 may be formed in an island arrangement structure in which a plurality of heat transfer layers 811 are formed on the infrared absorption layer 812.

According to one embodiment of the present disclosure, in the interface layer 810 of the island structure, the heat transfer layer 811 may be locally located on the infrared absorption layer 812 to absorb infrared rays passing through the solar cell. Thus, heat based on absorbed infrared rays and heat generated by the solar cell when the solar cell is exposed to sunlight may be transferred to the thermoelectric device.

That is, by partially arranging heat transfer regions between the solar cell and the thermoelectric device, the interface layer 810 may absorb infrared rays passing through the solar cell, may increase space utilization, and may improve the power generation performance of the thermoelectric device.

For example, to efficiently use heat generated by the solar cell and generate additional energy from the thermoelectric device, the interface layer 810 may be included in the energy harvesting system.

Accordingly, the present disclosure may provide an energy harvesting system with increased space utilization between a solar cell and a thermoelectric device by selectively including an interface layer having either a double structure or an island arrangement structure between the solar cell and the thermoelectric device.

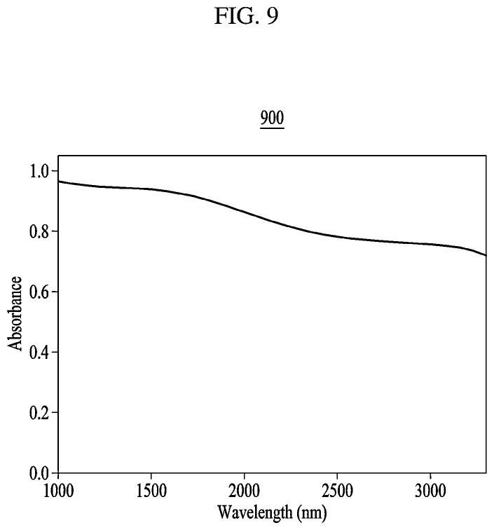

FIG. 9 is a graph for explaining the absorption characteristics of an infrared absorption layer constituting an interface layer according to one embodiment of the present disclosure.

Referring to FIG. 9, a graph 900 shows the absorption characteristics of a carbon-based material constituting the infrared absorption layer in a specific wavelength band.

Referring to the graph 900, it can be confirmed that the carbon-based material constituting the infrared absorption layer has an absorbance of about 80% or more in a wavelength band of about 1,000 nm to 3,000 nm.

According to one embodiment of the present disclosure, the infrared absorption layer absorbs near infrared rays of a wavelength band of about 1,000 nm to 3,000 nm.

For example, the infrared absorption layer may absorb near infrared rays corresponding to infrared rays passing through the solar cell, and may generate heat based on absorption of infrared rays. As a result, the temperature of the infrared absorption layer may be increased.

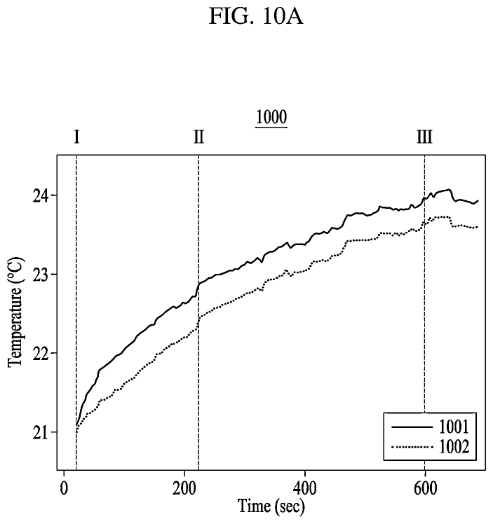

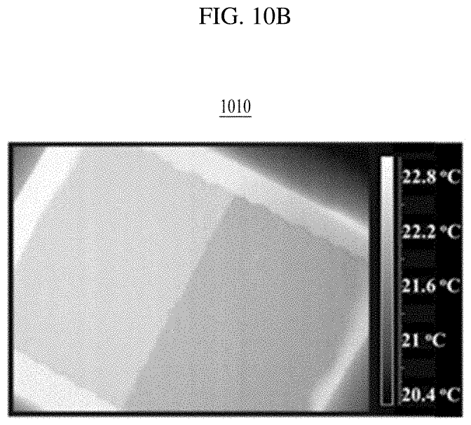

FIGS. 10A and 10B include a graph and an image for explaining the exothermic characteristics of an infrared absorption layer constituting an interface layer according to one embodiment of the present disclosure.

FIG. 10A shows temperature change over time in relation to the exothermic characteristics of the infrared absorption layer according to one embodiment of the present disclosure.

In a graph 1000 of FIG. 10A, a graph line 1001 may represent temperature change after adding an infrared absorption layer to a solar cell, and a graph line 1002 may represent temperature change of the solar cells over time.

Comparing the graph line 1001 and the graph line 1002, it can be seen that the measured temperature of the solar cell increases when the infrared absorption layer is added to the solar cell.

That is, according to one embodiment of the present disclosure, when the interface layer is added, the amount of heat transferred from the solar cell to the thermoelectric device may be significantly increased based on temperature increase due to absorption of infrared rays.

In the graph 1000 of FIG. 10A, the graph line 1001 may represent temperature change after the infrared absorption layer is added to the solar cell, and the graph line 1002 may represent the temperature change of the solar cell over time.

Comparing the graph line 1001 and the graph line 1002, it can be seen that the measured temperature of the solar cell is increased when the infrared absorption layer is added to the solar cell.

That is, according to one embodiment of the present disclosure, when the interface layer is added, the amount of heat transferred from the solar cell to the thermoelectric device may be increased.

FIG. 10B is a thermal image in relation to the exothermic characteristics of the infrared absorption layer according to one embodiment of the present disclosure.

Referring to FIG. 10B, in a thermal image 1010, an infrared absorption layer is formed only on a part of the solar cell, showing different temperatures.

It can be seen that the temperature on the left side is higher than the temperature on the right side in the thermal image 1010.

That is, according to one embodiment of the present disclosure, when the interface layer is added, the amount of heat transferred from the solar cell to the thermoelectric device may be increased based on temperature increase due to absorption of infrared rays.

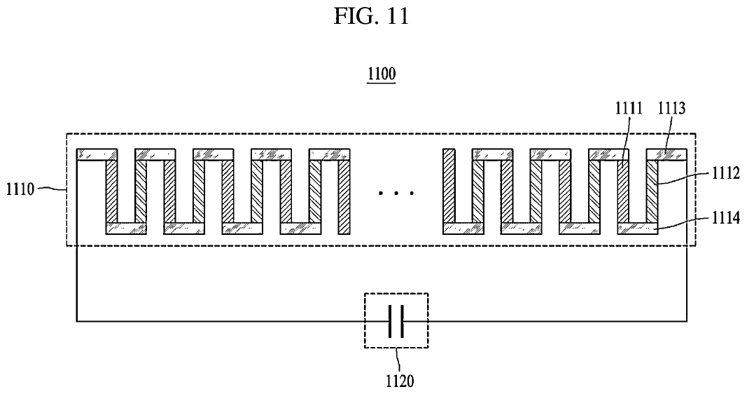

FIG. 11 illustrates an energy harvesting system using a thermoelectric device including a phase change material according to one embodiment of the present disclosure.

FIG. 11 illustrates a thermoelectric device including a phase change material according to one embodiment of the present disclosure and an energy harvesting system using the thermoelectric device.

Referring to FIG. 11, according to one embodiment of the present disclosure, an energy harvesting system 1100 includes a thermoelectric device 1110 and a capacitor 1120.

For example, the thermoelectric device 1110 includes a first electrode 1113, a second electrode 1114, and a first thermoelectric channel 1111 and a second thermoelectric channel 1112 between the first and second electrodes 1113 and 1114.

According to one embodiment of the present disclosure, any one of the first and second thermoelectric channels 1111 and 1112 is formed of a phase change material, and the other is formed of a thermoelectric material.

For example, the first and second thermoelectric channels 1111 and 1112 may be formed through heat treatment of the phase change material and the thermoelectric material through a screen printing process or a lithography process.

After the first and second thermoelectric channels 1111 and 1112 are formed, the first and second electrodes 1113 and 1114 may be formed to connect the first and second thermoelectric channels 1111 and 1112.

In addition, after the first and second electrodes 1113 and 1114 are formed, the first and second electrodes 1113 and 1114 may be connected through formation of the first and second thermoelectric channels 1111 and 1112.

For example, when the first thermoelectric channel 1111 is formed of a phase change material, and a heat source is located, the first thermoelectric channel 1111 may operate as a p-type thermoelectric channel. When a heat source is not located, the first thermoelectric channel 1111 may operate as a resistance channel.

In addition, the second thermoelectric channel 1112 may be formed of a thermoelectric material, and may operates as an n-type thermoelectric channel regardless of a heat source.

For example, the phase change material may include any one of VO₂, Cd₂Os₂O₇, NdNiO₃, SmNiO₃, and GdNiO₃, and the thermoelectric material may include any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂.

In addition, the first and second electrodes 1113 and 1114 may be formed of any one metal material of Au, Al, Pt, Ag, Ti, and W.

According to one embodiment of the present disclosure, in the thermoelectric device 1110, when a heat source is located on the first electrode 1113, both of the first and second thermoelectric channels 1111 and 1112 operate as a thermoelectric channel, and thus the thermoelectric device 1110 may perform power generation based on a temperature difference between the first and second electrodes 1113 and 1114.

That is, the thermoelectric device 1110 may be a thermoelectric device that generates electricity using the Seebeck effect that generates an electromotive force when a temperature difference between the first and second electrodes 1113 and 1114 occurs.

For example, the first electrode 1113 may operate as a hot electrode by the heat source, and the second electrode 1114 may operate as a cold electrode.

For example, the thermoelectric device 1110 may transfer a voltage generated based on a temperature difference between the first and second electrodes 1113 and 1114 to the capacitor 1120 so that the capacitor 1120 charges the voltage.

According to one embodiment of the present disclosure, when a voltage is transferred from the thermoelectric device 1110, the capacitor 1120 may charge the voltage. When a voltage is not transferred, the capacitor 1120 may discharge the charged voltage.

Here, a phenomenon in which current according to discharged voltage flows back to the thermoelectric device 1110 may occur, which is referred to as reverse current.

For example, the capacitor 1120 may be formed by a process such as lithography, thermal deposition, and spin coating. Since the capacitor 1120 performs charging and discharging, the capacitor 1120 may be referred to as a charging/discharging device.

For example, the capacitor 1120 may charge a voltage generated by the thermoelectric device 1110. When a heat source is not located on the first electrode 1113, and the thermoelectric device does not generate electricity, the capacitor 1120 may discharge the pre-charged voltage.

According to one embodiment of the present disclosure, in the thermoelectric device 1110, when a heat source is not located, the phase change material operates as a resistance channel to block reverse current based on a voltage discharged from the capacitor 1120 so that the reverse current does not flow in the reverse direction in the thermoelectric device 1110.

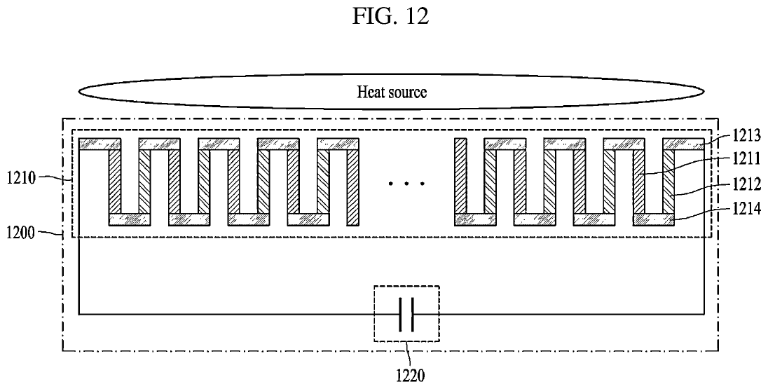

FIG. 12 illustrates an energy harvesting system when a heat source is present in the vicinity of a thermoelectric device including a phase change material according to one embodiment of the present disclosure.

FIG. 12 illustrates a case in which a heat source is located on a first electrode in a structure of a thermoelectric device including a phase change material according to one embodiment of the present disclosure and an energy harvesting system using the thermoelectric device.

Referring to FIG. 12, according to one embodiment of the present disclosure, an energy harvesting system 1200 includes a thermoelectric device 1210 and a capacitor 1220.

For example, the thermoelectric device 1210 includes a first electrode 1213, a second electrode 1214, and a first thermoelectric channel 1211 and a second thermoelectric channel 1212 between the first and second electrodes 1213 and 1214.

According to one embodiment of the present disclosure, in the thermoelectric device 1210, based on a temperature difference between the temperature of the first electrode 1213 by heat of a heat source located on the first electrode 1213 and the temperature of the second electrode 1214, a voltage may be generated from the first and second thermoelectric channels 1211 and 1212, and the generated voltage may be transferred to the capacitor 1220.

For example, since the first thermoelectric channel 1211 is formed of a phase change material and operates as a thermoelectric channel based on heat by a heat source, based on a temperature difference between heat by a heat source located on the first electrode 1213 and the temperature of the second electrode 1214, the first and second thermoelectric channels 1211 and 1212 may generate a voltage.

According to one embodiment of the present disclosure, the first thermoelectric channel 1211 may be formed of a phase change material. The phase change material has a polycrystal or crystal structure at high temperature by a heat source and has low resistance. Thus, the phase change material may operate as a thermoelectric channel.

For example, according to increased temperature based on a heat source, in the thermoelectric device 1210, the first thermoelectric channel 1211 may operate as a thermoelectric channel, and the first and second thermoelectric channels 1211 and 1212 may generate a voltage.

For example, the capacitor 1220 may charge a voltage transferred from the thermoelectric device 1210.

That is, in the energy harvesting system 1200, when a heat source is located on the thermoelectric device 1210, the thermoelectric device 1210 transfers heat of the heat source to the first thermoelectric channel 1211 through the first electrode 1213, and a phase change material forming the first thermoelectric channel 1211 operates as a thermoelectric channel. Thus, based on a temperature difference between the first and second electrodes 1213 and 1214, a voltage may be generated through the first and second thermoelectric channels 1211 and 1212, and the capacitor 1220 may be charged with the generated voltage.

Accordingly, according to the present disclosure, in the energy harvesting system, when a heat source is located in the vicinity of the thermoelectric device, a phase change material forming the thermoelectric channel of the thermoelectric device operates as a thermoelectric channel to generate electricity. When the heat source is not located, the phase change material operates as a resistance channel and operates as a thermal switch to block reverse current caused by discharging of voltage stored in a capacitor.

In addition, the present disclosure may provide an energy harvesting system capable of increasing the lifespan and operating time of products when applied to wearable devices, non-powered sensors, household devices, industrial devices, and the like and serving as a core power supply source in various devices including household devices and industrial devices by using natural energy.

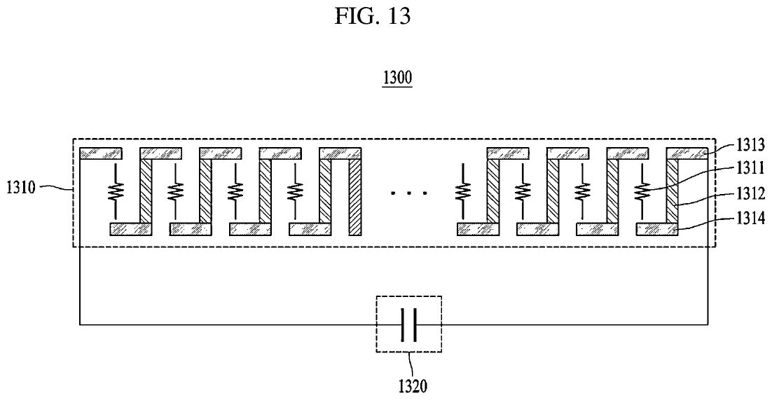

FIG. 13 illustrates an energy harvesting system when a heat source is not located in the vicinity of a thermoelectric device including a phase change material according to one embodiment of the present disclosure.

FIG. 13 illustrates a case in which a heat source is not located in the vicinity of an energy harvesting system in a structure of a thermoelectric device including a phase change material according to one embodiment of the present disclosure and the energy harvesting system using the thermoelectric device.

Referring to FIG. 13, according to one embodiment of the present disclosure, an energy harvesting system 1300 includes a thermoelectric device 1310 and a capacitor 1320.

For example, the thermoelectric device 1310 includes a first electrode 1313, a second electrode 1314, and a first thermoelectric channel 1311 and a second thermoelectric channel 1312 between the first and second electrodes 1313 and 1314.

According to one embodiment of the present disclosure, since a heat source is not located in the vicinity of the thermoelectric device 1310, the thermoelectric device 1310 is left at room temperature. Based on the fact that a phase change material forming the first thermoelectric channel 1311 has an amorphous structure at room temperature and has a very high resistance, thermoelectric device 1310 may operate as a resistance channel.

For example, when a voltage is not transferred from the thermoelectric device 1310 to the capacitor 1320, the capacitor 1320 may discharge a charged voltage to generate reverse current for applying current to the thermoelectric device 1310.

However, since the first thermoelectric channel 1311 operates as a resistance channel based on a phase change material, the thermoelectric device 1310 may block reverse current from the capacitor 1320.

That is, when a heat source is not present or is removed, the first thermoelectric channel 1311 is left at room temperature. At this time, the resistance of the phase change material increases. Accordingly, the first thermoelectric channel 1311 may block a voltage discharged from the capacitor 1320 to prevent the capacitor 1320 from being discharged.

That is, depending on the presence or absence of a heat source, the first thermoelectric channel 1311 may operate as a thermoelectric channel for charging a voltage to the capacitor 1320, or may serve as a thermal switch for preventing discharge of a voltage from the capacitor 1320.

Accordingly, the present disclosure may provide an energy harvesting system that blocks reverse current of a charging device without using an additional component such as a diode.

In addition, the present disclosure may provide an energy harvesting system that prevents a charged voltage from being discharged when power generation is not performed due to lack of a heat source while irregularly generating electricity depending on the presence or absence of a heat source.

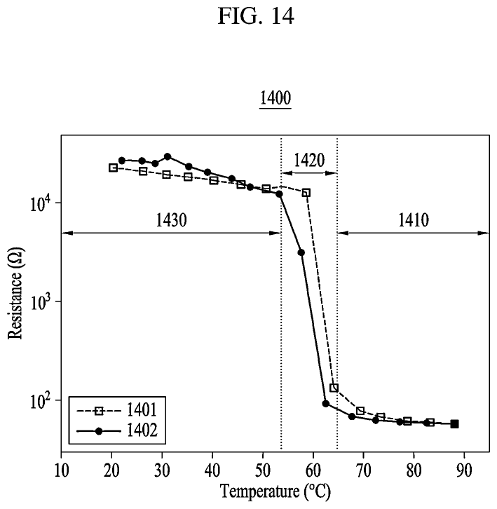

FIG. 14 is a graph for explaining the operating state of a thermoelectric device including a phase change material according to one embodiment of the present disclosure.

FIG. 14 shows that the thermoelectric device may operate as a thermoelectric channel or a resistance channel according to change in resistance according to the temperature of a phase change material according to one embodiment of the present disclosure.

Referring to FIG. 14, in a graph 1400, the horizontal axis represents change in temperature, and the vertical axis represents change in resistance.

In the graph 1400, a line 1401 may indicate change in resistance according to temperature change by heating.

In the graph 1400, a line 1402 may indicate change in resistance according to temperature change by cooling.

The graph 1400 shows that the phase change material may have a first state 1410, a second state 1430, and a transition state 1420 according to change in resistance according to temperature change.

That is, the first thermoelectric channel formed of the phase change material may have the first state 1410, the second state 1430, and the transition state 1420.

According to one embodiment of the present disclosure, when the temperature of any one thermoelectric channel formed of the phase change material is 65° C. to 90° C., which exceeds a phase transition temperature band, the phase change material may have the first state 1410 operating as a thermoelectric channel.

In addition, when the temperature of any one thermoelectric channel formed of the phase change material is 20° C. to 55° C., which is below the phase transition temperature band, the phase change material may have the second state 1430 operating as a resistance channel.

In addition, when the temperature of any one thermoelectric channel formed of the phase change material is 56° C. to 66° C., which is within the phase transition temperature band, the phase change material may have the transition state 1420 between the thermoelectric channel and the resistance channel.

For example, the thermoelectric device of the energy harvesting system generates a voltage by using a temperature difference between the first and second electrodes in the first state 1410 of the first thermoelectric channel, and transfers the generated voltage to a capacitor.

When the first thermoelectric channel of the thermoelectric device is in the first state 1410, the capacitor receives a voltage from the thermoelectric device and charges the voltage.

For example, the thermoelectric device of the energy harvesting system does not generate a voltage as the first thermoelectric channel operates as a resistance channel in the second state 1430 of the first thermoelectric channel.

In general, when a voltage is not transferred from the thermoelectric device, the capacitor may discharge a pre-charged voltage, and the discharged voltage may be transferred to the thermoelectric element as reverse current.

In the second state 1430 of the first thermoelectric channel, the first thermoelectric channel is a resistance channel. Thus, the thermoelectric device of the energy harvesting system according to one embodiment of the present disclosure may operates as a thermal switch that blocks reverse current.

That is, the first thermoelectric channel may operate as a thermal switch that generates a voltage at a temperature above a certain range and connects the thermoelectric device and the capacitor so that the generated voltage is transferred to the capacitor, or blocks current from being transferred from the capacitor to the thermoelectric device at a temperature below a certain range.

Accordingly, the present disclosure may provide an energy harvesting system that creates social and cultural innovation when applied to the 4th industry and wearable devices and helps overcome the energy crisis.

The present disclosure can improve the energy generation efficiency of an energy harvesting system by effectively transferring heat generated in a solar cell and heat induced by light passing through the solar cell to the upper portion of a thermoelectric device by including an interface layer between the solar cell and the thermoelectric device and by cooling the lower portion of the thermoelectric device without additional power consumption by including a cooling layer under the thermoelectric device.

The present disclosure can improve the performance of an energy harvesting system by improving the performance of a solar cell and the power generation performance of a thermoelectric device by dissipating heat of the solar cell without an additional power source by using a cooling patch layer made of a hygroscopic polymer or a radiative cooling layer that minimizes absorption of light of a sunlight spectrum and radiates heat under the radiative cooling layer to the outside to cool the surface temperature of a material or the temperature under the material.

The present disclosure can provide an energy harvesting system capable of maximizing space utilization by including an interface layer between a solar cell and a thermoelectric device, generating electrical energy through the solar cell, and generating electrical energy using heat of the solar cell through the thermoelectric device.

The present disclosure can provide an energy harvesting system capable of solving problems caused by heat generation of a solar cell by transferring heat generated by the solar cell and heat caused by absorption of infrared rays passing through the solar cell to a thermoelectric device and improving the power generation performance of the thermoelectric device.

The present disclosure can provide an energy harvesting system with increased space utilization between a solar cell and a thermoelectric device by selectively including an interface layer having either a double structure or an island arrangement structure between the solar cell and the thermoelectric device.

The present disclosure can provide an energy harvesting system, characterized in that, when heat is transferred to a thermoelectric device, a phase change material forming the thermoelectric channel of the thermoelectric device acts as the thermoelectric channel to generate electricity, and when heat is not transferred to the thermoelectric device, the phase change material acts as a resistance channel and acts as a thermal switch to block reverse current caused by discharging of voltage stored in a charging device such as a capacitor without using an additional component such as a diode.

The present disclosure can provide an energy harvesting system capable of increasing the lifespan and operating time of products when applied to wearable devices, non-powered sensors, household devices, industrial devices, and the like and serving as a core power supply source in various devices including household devices and industrial devices by using natural energy.

The present disclosure can provide an energy harvesting system that creates social and cultural innovation when applied to the 4th industry and wearable devices and helps overcome the energy crisis.

In the above-described specific embodiments, elements included in the invention are expressed in singular or plural in accordance with the specific embodiments shown.

However, it should be understood that the singular or plural representations are to be chosen as appropriate to the situation presented for the purpose of description and that the above-described embodiments are not limited to the singular or plural constituent elements. The constituent elements expressed in plural may be composed of a single number, and constituent elements expressed in singular form may be composed of a plurality of elements.

In addition, the present disclosure has been described with reference to exemplary embodiments, but it should be understood that various modifications may be made without departing from the scope of the present disclosure.

Therefore, the scope of the present disclosure should not be limited by the embodiments, but should be determined by the following claims and equivalents to the following claims.

### DESCRIPTION OF SYMBOLS

| | |
|---|---|
| 100: ENERGY HARVESTING | 110: SOLAR CELL |
| SYSTEM | |
| 120: INTERFACE LAYER | 130: THERMOELECTRIC DEVICE |
| 140: COOLING LAYER | |

What is claimed is:

1. An energy harvesting system, comprising:
a solar cell for generating electrical energy based on sunlight;
an interface layer located under the solar cell and comprising a heat transfer layer for transferring heat generated by the solar cell;
a thermoelectric device located under the interface layer, comprising a first electrode, a second electrode, and a thermoelectric channel located between the first and second electrodes, and configured to generate electrical energy based on a temperature difference between the first and second electrodes that occurs when heat generated by the solar cell is transferred to the first electrode through the heat transfer layer; and
a cooling layer located under the thermoelectric device and cooling the second electrode to increase the temperature difference.

2. The energy harvesting system according to claim 1, wherein the cooling layer is formed of any one of a cooling patch layer formed of a hygroscopic polymer and a radiative cooling layer formed by coating or dyeing the second electrode with a paint solution prepared by mixing a solvent and a binder for mechanically connecting nanoparticles or microparticles, a particle size and composition of which are determined by considering infrared emissivity and reflectance to incident sunlight in a wavelength range corresponding to a sky window and surfaces of the nanoparticles or microparticles.

3. The energy harvesting system according to claim 2, wherein the cooling patch layer has a three-dimensional network structure and a porous structure to store moisture, wherein, during daytime, the stored moisture evaporates and cools the second electrode, and during night time, supercooled vapor in an air liquefies on a surface that has a higher humidity than surroundings, allowing the cooling patch layer to store additional moisture.

4. The energy harvesting system according to claim 3, wherein the cooling patch layer is formed of any one polymer of a polyacrylic acid-based polymer, a polyvinyl alcohol-based polymer, a polyvinylpyrrolidone-based polymer, and a natural polymer,
wherein the natural polymer comprises at least one of carrageenan, agar, glucomannan, sodium alginate, gum arabic, and cellulose derivatives.

5. The energy harvesting system according to claim 2, wherein the nanoparticles or microparticles comprise a mixture of at least one nanoparticle or microparticle material of SiO₂, Al₂O₃, CaCO₃, CaSO₄, c-BN, ZrO₂, MgHPO₄, Ta₂O₅, AlN, LiF, MgF₂, HfO₂, and BaSO₄ and the at least one nanoparticle or microparticle material, and
the binder comprises at least one binder material of dipentaerythritol hexaacrylate (DPHA), polytetrafluoroethylene (PTFE), polyurethane acrylate (PUA), ethylene tetra fluoro ethylene (ETFE), polyvinylidene fluoride (PVDF), an acrylic polymer, a polyester-based polymer, and a polyurethance-based polymer.

6. The energy harvesting system according to claim 2, wherein the radiative cooling layer cools the second electrode by absorbing and emitting long wavelength infrared rays of 8 μm to 13 μm corresponding to the wavelength range corresponding to a sky window based on the infrared emissivity and reflecting ultraviolet rays and near infrared rays of 0.3 μm to 2.5 μm corresponding to the incident sunlight based on the reflectance.

7. The energy harvesting system according to claim 1, wherein the interface layer comprises an infrared absorption layer for absorbing infrared rays passing through the solar cell,
the heat transfer layer transfers heat based on the infrared absorption layer to the first electrode, and
the thermoelectric device generates electrical energy by using both heat generated by the solar cell and heat based on the infrared absorption layer.

8. The energy harvesting system according to claim 7, wherein the interface layer is formed in any one of a dual structure and an island arrangement structure,
wherein, in the dual structure, the infrared absorption layer is disposed on the heat transfer layer, and the dual structure is configured to absorb infrared rays passing through the solar cell and transfer, to the thermoelectric device, heat based on the absorbed infrared rays and heat generated by the solar cell when the solar cell is exposed to sunlight, and
in the island structure, the heat transfer layer is locally disposed on the infrared absorption layer, and the island structure is configured to absorb infrared rays passing through the solar cell and transmit, to the thermoelectric device, heat based on the absorbed infrared rays and heat generated by the solar cell when the solar cell is exposed to sunlight.

9. The energy harvesting system according to claim 7, wherein the infrared absorption layer is formed of a carbon-based material, and the heat transfer layer is formed of at least one heat conductive material of boron nitride (BN), reduced graphene oxide (rGO), aluminum nitride (AlN), silicon carbide (SiC), and beryllium oxide (BeO).

10. The energy harvesting system according to claim 1, wherein the first and second electrodes are formed of any one metal material of Au, Al, Pt, Ag, Ti, and W, and the thermoelectric channel is formed of any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂.

11. The energy harvesting system according to claim 1, wherein the solar cell comprises at least one of a silicon (Si) solar cell, a dye-responsive solar cell, a monocrystalline solar cell, a polycrystalline solar cell, and a thin-film solar cell.

12. The energy harvesting system according to claim 1, wherein the thermoelectric device comprises the thermoelectric channel consisting of a first thermoelectric channel and a second thermoelectric channel, any one of the first and second thermoelectric channels is formed of a phase change material, and the other is formed of a thermoelectric material,
wherein, when heat is transferred from the heat transfer layer, the phase change material operates as a thermoelectric channel, and
when heat is not transferred, the phase change material operates as a resistance channel to block reverse current caused by discharging of voltage in a capacitor charged with the generated electrical energy.

13. The energy harvesting system according to claim 12, wherein the first thermoelectric channel is formed of any one of VO₂, Cd₂Os₂O₇, NdNiO₃, SmNiO₃, and GdNiO₃ as the phase change material, operates as a p-type thermoelectric channel when a heat source based on the transferred heat is located, and operates as a resistance channel when the heat source is not located, and
the second thermoelectric channel is formed of any one synthetic nanoparticle material of Ag₂Te, Ag₂Se, Cu₂Se, Cu₂Te, HgTe, HgSe, Bi₂Te₃, BiSeTe, BiSbTe, Ti₃C₂, Mo₂C, Mo₂Ti₂C3, MoS₂, and WS₂ as the thermoelectric material and operates as an n-type thermoelectric channel regardless of the heat source.

14. The energy harvesting system according to claim 12, wherein, in the any one thermoelectric channel, when temperature exceeds a phase transition temperature band, the phase change material is in a first state in which the phase change material operates as the thermoelectric channel; when the temperature is below the phase transition temperature band, the phase change material is in a second state in which the phase change material operates as the resistance channel; and when the temperature is within the phase transition temperature band, the phase change material is in a transition state between the thermoelectric channel and the resistance channel.
